(19) United States
(12) Patent Application Publication
(10) Pub. No.: US 2006/0148234 A1
(43) Pub. Date: Jul. 6, 2006

(54) Non-via method of connecting magnetoelectric elements with conductive line

(75) Inventors: Young-shying Chen, Hsinchu County (TW); Hong-Hui Hsu, Changhua County (TW); Wei-Chuan Chen, Taipei County (TW); Chun-Fei Chuang, Chiayi County (TW); Ming-Jer Kao, Tainan City (TW)

Correspondence Address: BIRCH STEWART KOLASCH & BIRCH, PO BOX 747, FALLS CHURCH, VA, 22040-0747, US

(73) Assignee: INDUSTRIAL TECHNOLOGY RESEARCH INSTITUTE

(21) Appl. No.: 11/154,632

(22) Filed: Jun. 17, 2005

(30) Foreign Application Priority Data
Dec. 31, 2004 (TW) 93141732

(51) Int. Cl. H01L 21/00; H01L 21/4763

(52) U.S. Cl. 438/618; 438/3

(57) ABSTRACT

A non-via method of connecting a magnetoelectric element with a conductive line. A magnetoelectric element is formed on a substrate, and spacers are formed on side walls of the magnetoelectric element. A dielectric layer is deposited over the substrate and magnetoelectric element and planarized to a level above the magnetoelectric element. The dielectric layer is etched to expose the upper surface of the magnetoelectric element, and a conductive line is formed on the magnetoelectric element.

### BACKGROUND

The present invention relates to a non-via method, and more specifically to a non-via method of connecting a magnetoelectric element with a conductive line.

Magnetoresistive random access memory (MRAM) is an increasingly popular new generation memory, following SRAM, DRAM, and flash memory, due to its non-volatility, high integration, high readout speed, anti-radiation, and high compatibility with CMOS fabrication.

MRAM structure comprises upper and lower conductive metal layers in X and Y-orientations, respectively, and a magnetoelectric element disposed therebetween such as giant magnetoresistance (GMR), magnetic tunneling junction (MTJ), or tunneling magnetoresistance (TMR), wherein the conductive metal layers are bit line and word line, respectively.

MTJ is a stacked structure of multiple layers of magnetic metal material comprising a free layer, a tunnel barrier layer, a pinned layer, and an anti-ferromagnetic layer, wherein the free layer and pinned layer, preferably, comprise ferromagnetic materials. The pinned layer exhibits a fixed magnetization orientation due to interactions with the anti-ferromagnetic layer. The free layer, however, exhibits an altered magnetization orientation due to various induced magnetic fields from bit line and word line. Resistance of MTJ can thus be altered by presentation of parallel or perpendicular magnetization orientations between the free layer and pinned layer. When current is applied to MTJ, data can be read out by voltage type to determine “1” or “0” memory state.

With reduction of memory size, via processes connecting MTJ with word line have suffered from problems such as alignment shift in development and control of etching depth, hindering progress of size reduction. Additionally, read-in current has also approached load-bearing limitations of metal line, producing electron migration.

Related non-via methods of connecting a MTJ with a word line are described in the following. For example, as disclosed in U.S. Pat. No. 6,744,608, a conductive or dielectric hard mask layer is firstly formed over a MTJ. A dielectric layer overlying the MTJ is then planarized by chemical mechanical polishing (CMP) until the hard mask layer is exposed. The conductive hard mask layer can remain on the MTJ surface. The dielectric layer, however, must be removed by additional steps. A word line fabrication then proceeds. The method solves alignment shift in development and provides precise control of etching depth, high magnetic field efficiency, and low read-in current due to direct connection between the word line and the MTJ.

Nevertheless, the related method cannot precisely control the depth of polishing to the hard mask layer. Over-polishing to the MTJ usually occurs, because various control parameters, such as polishing pad, polishing solution, and polishing end point, must be considered simultaneously. Even when the dielectric layer is polished to near the upper surface of the hard mask layer, polishing program or apparatus must further be adjusted to ensure formation of a smooth dielectric layer plane, avoiding dishing. Further, with requirement for estimation of attrition of polishing pad, alteration of polishing solution, and control of polishing end point, such techniques become more complicated.

As disclosed in U.S. Pat. No. 6,783,995, a sacrificial cap layer or spacers are formed over a MTJ or on side walls thereof to protect the MTJ from etching. After removing the sacrificial cap layer, a metal line fabrication proceeds.

### SUMMARY

The invention provides a non-via method of connecting a magnetoelectric element with a conductive line, comprising the following steps. A magnetoelectric element is formed on a substrate. Spacers are formed on side walls of the magnetoelectric element. A dielectric layer is deposited over the substrate and magnetoelectric element. The dielectric layer is planarized to a level above the magnetoelectric element. The dielectric layer is etched to expose the upper surface of the magnetoelectric element. A conductive line is finally formed on the magnetoelectric element.

The non-via method solves alignment shift in development and provides precise control of etching depth, making it suitable for use in size reduction of magnetoelectric elements.

The non-via method also reduces read-in current and power consumption of MRAM during the read-in period, because the word line is directly pasted on the magnetoelectric element, increasing magnetic field efficiency.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a flow chart of a non-via method of the invention.

FIGS. 2A˜2F are cross sections of a method of connecting a magnetoelectric element with a conductive line of the invention.

FIGS. 3A˜3B are cross sections of another method of connecting a magnetoelectric element with a conductive line of the invention.

### DETAILED DESCRIPTION

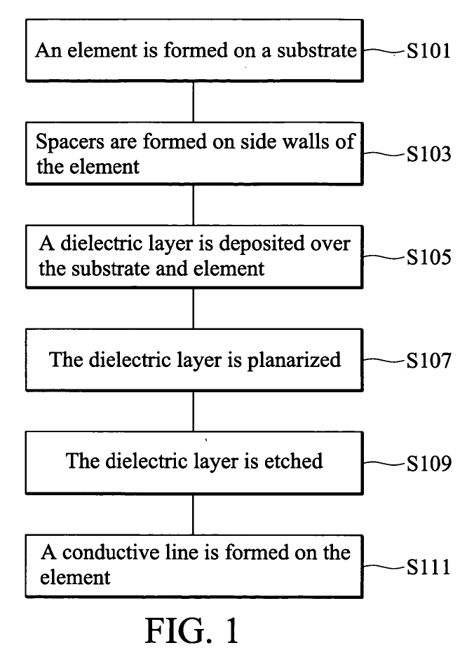

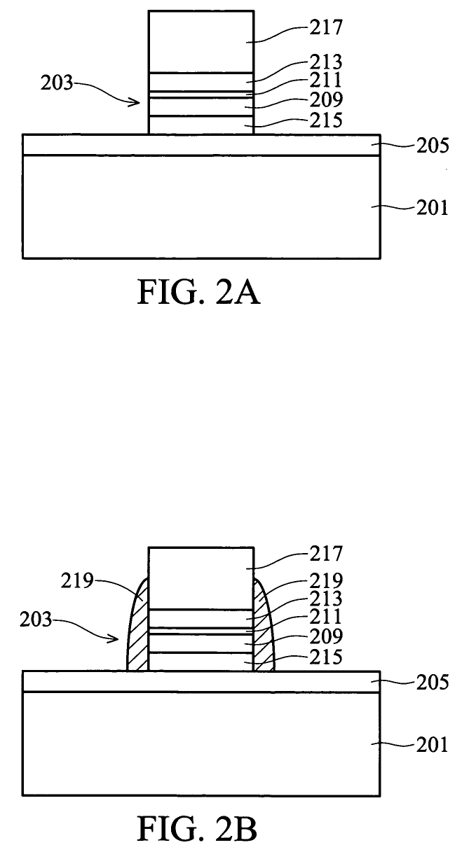

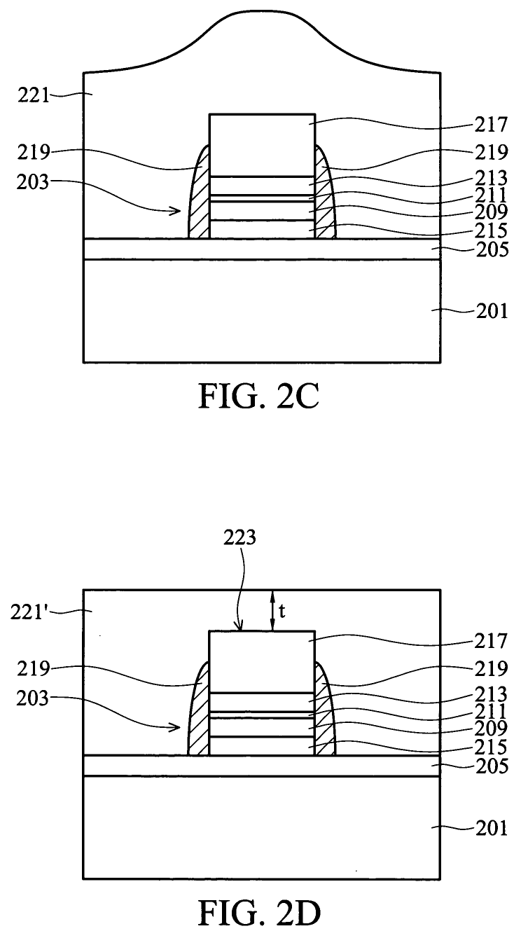

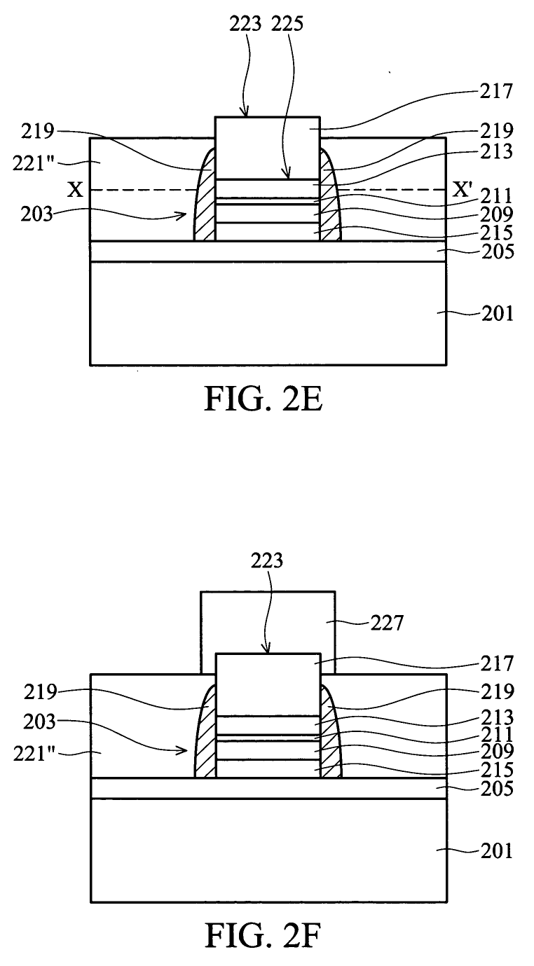

Although the invention is described by way of the following example regarding a non-via method of connecting a conductive line with a MTJ element, the invention is not limited thereto. The example is illustrated in FIG. 1 and FIGS. 2A˜2F.

Referring to FIG. 1 and FIG. 2A, a MTJ element 203 is formed on a substrate 201 in step S101, wherein a conductive line 205 is formed on or in the substrate 201, preferably a Cu or Al conductive line, and the MTJ is formed thereon. The substrate 201 can further comprise other semiconductor devices such as CMOS connecting the MTJ with the conductor line 205. In order to simplify the drawing, the semiconductor devices are not illustrated therein. MTJ 203 is a stacked structure of multiple layers mainly comprising a pinned layer 209, a tunnel barrier layer 211, and a free layer 213, wherein the pinned layer 209 and the free layer 213 are magnetic materials and the tunnel barrier layer 211 is disposed therebetween.

The pinned layer 209 and the free layer 213 are preferably ferromagnetic materials such as Fe, Co, Ni, or combinations thereof. The tunnel barrier layer 211 is preferably Al₂O₃ or MgO. Magnetization oritenation of the pinned layer 209 is fixed and its coercive field (Hc) increased by an anti-ferromagnetic layer 215 with ferromagnetic-anti-ferromagnetic exchange coupling interaction to stabilize magnetic moment. Magnetoelectric elements provided by the invention are not limited to such MTJ elements and may alternatively comprise MTJ including other structures or layers or other element types.

The top layer of the MTJ 203 comprises a hard mask layer 217, preferably a conductive hard mask layer comprising Ta, Ti, Cr, TaN, or TiN, preferably Ta. The hard mask layer 217, preferably has a thickness of about 400˜600 Å. The completed MTJ structure is formed by deposition, development, and etching. The hard mask layer 217 is used as a hard mask of the MTJ 203 during etching.

Next, referring to FIG. 1 and FIG. 2B, spacers 219 are formed on side walls of the MTJ 203 and hard mask layer 217 in step S103. The spacers 219 are formed by, for example, conformal material layer deposition over the substrate 201 and MTJ 203 comprising the hard mask layer 217 at the top layer thereof. Spacers 219 are formed by anisotropic etching to protect the side walls of the MTJ 203. The spacers 219, preferably comprise nitride such as silicon nitride or silicon nitride grown at low temperature.

Next, referring to FIG. 1 and FIG. 2C, a dielectric layer 221 is deposited over the substrate 201 and MTJ 203 by related deposition methods such as chemical vapor deposition, physical vapor deposition, or spin coating, in step S105. Preferably, the dielectric layer has etching selectivity to the hard mask layer 217 and spacers 219. Thus, the hard mask layer 217 and spacers 219 protect the MTJ 203 during etching. To avoid deteriorated magnetoelectrical performance of the MTJ 203 at high temperatures, the dielectric layer 221, is preferably oxide material, such as silicon oxide, grown at low temperature.

Next, referring to FIG. 1 and FIG. 2D, the dielectric layer 221 is planarized to a level t above the upper surface 223 of the hard mask layer 217 at the top of the MTJ 203 to form a dielectric layer structure 221′ in step S107. The planarization can be performed by related chemical mechanical polishing. The polishing conditions are easily controlled, because determination of the level t above the upper surface 223 of the hard mask layer 217 can be rough, without precise measurement. The level t is preferably less than 1000 Å.

Next, referring to FIG. 1 and FIG. 2E, the dielectric layer 221′ is etched back to expose the upper surface 223 of the hard mask layer 217 at the top of the MTJ 203 in step S109, a critical step of the invention. The etching is preferably dry etching such as plasma etching or high density plasma (HDP) etching. Generally, over etching to the location lower than the upper surface 223 of the hard mask layer 217 or even to lower than the upper surface 225 of the free layer 213 may easily occur, as shown in FIG. 2E by the X-X′ dotted line. The dielectric layer 221, however, has etching selectivity to the hard mask layer 217 and spacers 219 so that the MTJ 203 is completely protected during etching, avoiding short circuit caused by contact between subsequently formed conductive line and the side walls of the MTJ 203.

Next, referring to FIG. 1 and FIG. 2F, a conductive layer, such as Al layer, is deposited over the MTJ 203 and dielectric layer 221′ in step S111. The conductive layer is then defined to form a conductive line 227 connected with the hard mask layer 217 at the top of the MTJ 203 by development and etching. The conductive line 227 may be wider than the MTJ 203. The hard mask layer 217 can remain due to conductivity. Referring to FIG. 2F, the conductive line 227 is directly pasted on the hard mask layer 217 at the top of the MTJ 203, without via process. Thus, tolerance of alignment shift in development is increased, contributing to reduction of device size, increase in magnetic efficiency, and conservation of power.

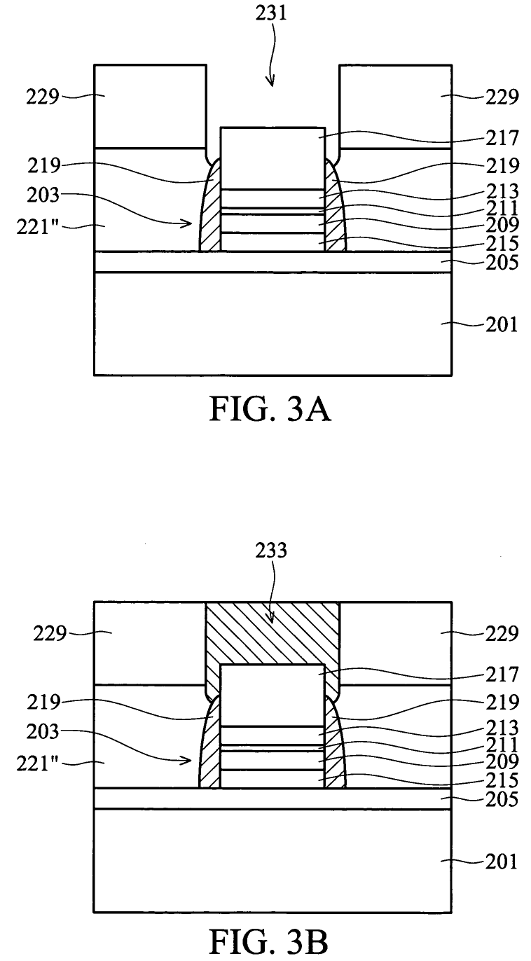

Cu is a mainstay of conductive lines due to its low resistance and high anti-electron mobility. Cu metal, however, is unsuitable for direct etching as described above. Thus, the invention provides another example regarding a Cu damascene process, illustrated in FIG. 3A˜3B.

Referring to FIG. 2E, a dielectric material layer is deposited over the MTJ 203 and dielectric layer 221′. The dielectric material layer comprises fluorinated silicate glass (FSG), un-doped silicate glass (USG), low K material, or black diamond. A conductive line trench 231 is then formed in the dielectric material layer 229 by development and etching, as shown in FIG. 3A. Tolerance of alignment shift in development is increased due to the spacers 219 used as an etching stop layer. The trench 231 may be wider than the MTJ 203.

Next, a conductive material layer, such as Cu, Al, or other metals, is deposited into the conductive line trench 231 and over the dielectric material layer 229. Next, the conductive material layer above the dielectric material layer 229 is removed by chemical mechanical polishing to form a conductive line 233, as shown in FIG. 3B.

Damascene processes suitable for use in the invention are not limited to those shown in FIG. 3A˜3B, with any proper modifications and similar arrangements thereof allowable. For example, addition of etching stop layer such as silicon nitride or silicon carbide, diffusion barrier layer such as Ti, Ta, W, or nitride thereof, or seed layer, or replacement of MTJ by giant magnetoresistance (GMR).

The spacers and hard mask layer provided by the invention can be used as barrier layers to protect the MTJ during the dielectric layer etching and trench etching in metal damascene process. Additionally, the two-stage removal process of dielectric layer solves many related problems caused by chemical mechanical polishing.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A non-via method of connecting a magnetoelectric element with a conductive line, comprising:
forming a magnetoelectric element on a substrate;
forming spacers on side walls of the magnetoelectric element;
depositing a dielectric layer over the substrate and magnetoelectric element;
planarizing the dielectric layer to a level above the magnetoelectric element;
etching the dielectric layer to expose the upper surface of the magnetoelectric element; and
forming a conductive line on the magnetoelectric element.

2. The non-via method as claimed in claim 1, wherein the magnetoelectric element comprises a magnetic tunnel junction (MTJ) element.

3. The non-via method as claimed in claim 1, wherein the top layer of the magnetoelectric element comprises a hard mask layer.

4. The non-via method as claimed in claim 3, wherein the hard mask layer is a conductive layer.

5. The non-via method as claimed in claim 3, wherein the hard mask layer comprises Ta, Ti, Cr, TaN, or TiN.

6. The non-via method as claimed in claim 3, wherein the hard mask layer has a thickness of about 400˜600 Å.

7. The non-via method as claimed in claim 1, wherein the spacers comprise Si₃N₄ or Si₃N₄ grown at low temperature.

8. The non-via method as claimed in claim 1, wherein the dielectric layer is planarized by chemical mechanical polishing (CMP).

9. The non-via method as claimed in claim 1, wherein the level above the magnetoelectric element is less than 1000 Å.

10. The non-via method as claimed in claim 1, wherein the dielectric layer is etched by dry etching.

11. The non-via method as claimed in claim 1, wherein the dielectric layer comprises oxide.

12. The non-via method as claimed in claim 1, forming the conductive line on the magnetoelectric element, comprising:
depositing a conductive layer over the dielectric layer and the exposed upper surface of the magnetoelectric element; and
defining the conductive layer to form the conductive line.

13. The non-via method as claimed in claim 12, wherein the conductive layer comprises Al.

14. The non-via method as claimed in claim 1, forming the conductive line on the magnetoelectric element, comprising:
depositing a dielectric material layer over the dielectric layer and the exposed upper surface of the magnetoelectric element;
patterning the dielectric material layer to form a conductive line trench;
depositing a conductive material layer into the conductive line trench and over the dielectric material layer; and
removing the conductive material layer above the dielectric material layer to form the conductive line.

15. The non-via method as claimed in claim 14, wherein the conductive material layer comprises Cu or Al.

16. The non-via method as claimed in claim 1, further comprising forming another conductive line on or in the substrate.
